(19) United States
(12) Patent Application Publication
(10) Pub. No.: US 2025/0275089 A1
(43) Pub. Date: Aug. 28, 2025

(54) HYBRID HEAT-TRANSFER COMPONENTS AND SYSTEMS

(71) Applicant: CoolIT Systems, Inc., Calgary (CA)

(72) Inventor: Mohammad Reza Najjari, Calgary (CA)

(21) Appl. No.: 19/063,297

(22) Filed: Feb. 26, 2025

Related U.S. Application Data
(60) Provisional application No. 63/558,645, filed on Feb. 27, 2024.

(51) Int. Cl. H05K 7/20

(52) U.S. Cl. CPC H05K 7/20254

(57) ABSTRACT

A hybrid cold-plate is configured to cool a processing unit and an adjacent heat-generating component. The hybrid cold-plate has an internally cooled cold plate and a passive heat-transfer component. The internally cooled cold plate has a first thermal interface region configured to be placed into thermal contact with the processing unit and a second thermal interface region configured to be placed into thermal contact with the passive heat-transfer component. The passive heat-transfer component has a first thermal interface region configured to placed into thermal contact with the adjacent heat-generating component and a second thermal interface region configured to be placed into thermal contact with the second thermal interface region of the internally cooled cold plate. A cover plate positioned overtop the internally cooled cold plate and the passive heat-transfer component can be configured to urge the internally cooled cold plate toward the processing unit, the passive heat-transfer component toward the heat-generating component, and the passive heat-transfer component toward the internally cooled cold plate.

### CROSS-REFERENCE TO RELATED APPLICATIONS

This application claims benefit of and priority from provisional U.S. Patent Application No. 63/558,645, filed Feb. 27, 2024, the contents of which is hereby incorporated by reference to the same extent as if reproduced herein in full, for all purposes.

This application and the subject matter disclosed herein (collectively referred to as the “disclosure”) pertain to principles and techniques described in co-pending U.S. Patent Application Ser. No. 63/526,917, filed on Jul. 14, 2023, and U.S. patent application Ser. No. 18/297,561, filed on Apr. 7, 2023, the contents of which patent applications are hereby incorporated by reference to the same extent as if reproduced herein in full, for all purposes.

### FIELD

This disclosure generally concerns components that facilitate or provide hybrid modes of heat transfer, together with associated systems and methods. More particularly, but not exclusively, this disclosure pertains to liquid- and two-phase cooling systems incorporating a passive component that transfers heat from one or more heat-generating components to a liquid- or a two-phase cold plate that also receives heat from another heat-generating component, together with related methods and systems.

### BACKGROUND INFORMATION

New generations of electronic components, such as, for example, memory components, microprocessors, graphics processors, and power electronics semiconductor devices, produce increasing amounts of heat when operating. In addition, electronic devices, such as, for example, servers, computers, game consoles, power electronics, communications and other networking devices, batteries, and so on, arrange electronic component in close proximity with each other. If the heat is not removed at a sufficient rate, the components can overheat, decreasing performance, reliability, or both, and in some cases component damage or failure.

The prior art has addressed these challenges using air cooling, liquid cooling (e.g., involving liquid coolant, e.g., water, glycol, polyethylene glycol, etc.), or a combination thereof, to transfer and dissipate heat from electronic components to an ultimate heat sink, e.g., the atmosphere.

Conventional air cooling relies on natural convection or uses forced convection (e.g., a fan mounted near a heat producing component) to replace heated air with cooler ambient air around the component. Such air-cooling techniques can be supplemented with a conventional “heat sink,” which often is a plate of a thermally conductive material (e.g., aluminum or copper) placed in thermal contact with the heat-producing component. The heat sink can spread heat from the component to a larger area for dissipating heat to the surrounding air. Some heat sinks include “fins” to further increase the surface area available for heat transfer and thereby to improve the transfer of heat to the air. Some heat sinks include a fan to force air among the fins and are commonly referred to in the art as “active” heat sinks. Some have previously proposed removing heat from a plurality of heat-generating components arranged in close proximity with each other using a single, air-cooled heat sink.

Liquid cooling improves cooling performance compared to air cooling techniques described above, as many liquids, e.g., water, have significantly better heat transfer capabilities than air. FIG. 1 illustrates various components of a liquid cooling loop 100. The cooling loop 100 typically operates by (1) transferring heat, \dot{Q}ᵢₙ, from a heat-generating electronic component (not shown) to a cool liquid passing through a heat exchanger 110 (sometimes referred to in the art as a “cold plate” or a “heat sink”) placed in thermal contact with the heat-generating component, (2) transporting the heat absorbed by the liquid to a remote radiator 120, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) dissipating the heat, \dot{Q}ₒᵤₜ, from the remote radiator to another medium (e.g., air or facility water passing through the remote radiator), and (4) returning cooled liquid to the heat exchanger (or heat sink).

### SUMMARY

Presently disclosed cooling devices and systems provide further improved cooling performance compared to previously proposed cooling devices and systems. For example, in contrast to previously proposed techniques that provide a large, single-mode heat sink (or cold plate) placed in thermal contact with a plurality of closely arranged heat-generating components, disclosed hybrid cold plates combine, for example, a liquid- or a refrigerant-cooled cold plate with a passive heat-transfer component. Such a hybrid cold plate can have a significantly lower mass compared to a large, single-mode heat sink while effectively cooling a plurality of closely arranged heat-generating components.

Some disclosed hybrid cold plates provide a liquid- or a refrigerant-cooled cold plate for (1) directly cooling one or more, e.g., high-power, low-temperature (or both), heat-generating components; and (2) indirectly cooling one or more other, e.g., relatively-lower power, higher-temperature (or both), heat-generating components. For example, such a hybrid cold plate can provide a passive heat-transfer component to transfer heat from the one or more indirectly cooled heat-generating components to the liquid- or a refrigerant-cooled cold plate. By way of further example, the passive heat-transfer component can conductively receive heat from each of the one or more heat-generating components indirectly cooled by the liquid- or a refrigerant-cooled cold plate. The passive heat-transfer component can also convey such received heat and transfer it to the liquid- or refrigerant cooled cold plate, which in turn facilitates a transfer of such heat to a coolant (or a refrigerant) passing through the cold plate.

In some embodiments, the passive heat-transfer component includes a thermally conductive solid that conveys heat from the one or more heat-generating components to the liquid- or refrigerant-cooled cold plate. For example, such a thermally conductive solid can span across one or more components and facilitate heat transfer from the one or more components to a liquid-cooling loop (or a two-phase cooling loop). By way of further example, the thermally conductive solid can conduct heat from the one or more heat-generating components to an internally cooled cold plate, which in turn can facilitate a transfer of the heat to a single- or a two-phase coolant passing through the cold plate.

In some embodiments, the passive heat-transfer component includes a passive, two-phase cold plate that conveys heat from the one or more heat-generating components to the liquid- or refrigerant-cooled cold plate spans. For example, such a passive, two-phase cold plate can span across one or more components and facilitate heat transfer from the one or more components to a liquid-cooling loop (or a two-phase cooling loop). By way of further example, the a passive, two-phase cold plate can convey heat from the one or more heat-generating components to an internally cooled cold plate, which in turn can facilitate a transfer of the heat to a single- or a two-phase coolant passing through the internally cooled cold plate.

As but one illustrative example, one or more passive, two-phase cold plates, e.g., vapor-chamber cold plates, heat-pipe cold plates, etc., can thermally couple with (e.g., conductively) one or more heat-generating components positioned near, for example, a processing unit. Similarly, a cold plate fluidly coupled with a single-phase or a two-phase cooling loop can be thermally coupled with (e.g., a conductively coupled with) the processing unit, and heat generated by the processing unit can be transferred to the coolant circulating through the cooling loop. Further, the one or more passive, two-phase cold plates can be thermally coupled with (e.g., conductively) the cold plate fluidly coupled with the single-phase or two-phase cooling loop, enhancing cooling of the one or more heat-generating components by transferring heat from those components to the cold plate, and thereby to a coolant flowing through the cooling loop.

According to a first aspect, a hybrid cold plate includes a passive heat-transfer component defining a first thermal-interface region configured to be placed into thermal contact with a heat-generating component. The passive heat-transfer component has a second thermal-interface region configured to be placed into thermal contact with a corresponding surface of an internally cooled cold plate. The hybrid cold plate also includes a cover plate configured to overlie the passive heat-transfer component and to urge the passive heat-transfer component in compression against the heat-generating component, the surface of the internally cooled cold plate, or both.

In some hybrid cold plate embodiments, the cover plate defines a first major surface and an opposed second major surface. The second major surface can define a recessed region configured to receive a portion of the passive heat-transfer component therein, e.g., when the passive heat-transfer component is placed into thermal contact with the heat-generating component, the internally cooled cold plate, or both.

When the passive heat-transfer component is placed into thermal contact with the heat-generating component, the internally cooled cold plate, or both, the passive heat-transfer component can be positioned between the heat-generating component and the cover plate.

A portion of the cover plate configured to overlie the passive heat-transfer component can be formed of a thermally conductive metallic alloy, e.g., to enhance heat transfer between the passive heat-transfer component and the internally cooled cold plate compared to embodiments that lack a thermally conductive cover plate.

A thermal interface material can be positioned between the cover plate and the passive heat-transfer component. A thermal interface material can alternatively or additionally be positioned between the passive heat-transfer component and the heat generating component.

The cover plate can have a unitary construction.

The cover plate can define an aperture configured to receive a raised portion of the internally cooled cold plate.

The passive heat-transfer component can be a first passive heat-transfer component configured to be placed into thermal contact with a first heat-generating component. Some hybrid cold plate embodiments also include a second passive heat-transfer component configured to be placed into thermal contact with a second heat-generating component.

The first thermal-interface region of the passive heat-transfer component can be an evaporator region and the second thermal-interface region of the passive heat-transfer component can be a condenser region.

The passive heat-transfer component can be configured to transfer heat from the heat generating component to the internally cooled cold plate.

The heat-generating component can be a first heat-generating component, and the hybrid cold-plate can also include the internally cooled cold plate. The internally cooled cold plate can define a first heat-transfer surface configured to be placed into thermal contact with a corresponding heat-transfer surface of the second heat-generating component, and wherein the internally cooled cold plate defines a second heat-transfer surface configured to be placed into thermal contact with the second thermal-interface region of the cover plate.

A thermal interface material can be positioned between the first heat-transfer surface of the heat-transfer of the second heat-generating component.

The heat-generating component can include a bare die and the internally cooled cold plate can be bonded with the bare die.

According to a second aspect, a cooling system is configured to cool a processing unit and a heat-generating component positioned adjacent the processing unit. The cooling system includes a hybrid cold-plate configured to cool the processing unit and the heat-generating component by transferring heat to a coolant, as well as a heat exchanger configured to reject the heat from the coolant to another medium. The hybrid cold-plate includes an internally cooled cold plate having a first thermal interface region configured to be placed into thermal contact with the processing unit and a second thermal interface region configured to be placed into thermal contact with a passive heat-transfer component. The hybrid cold-plate also includes a passive heat-transfer component having a first thermal interface region configured to be placed into thermal contact with the heat-generating component and a second thermal interface region configured to be placed into thermal contact with the second thermal interface region of the internally cooled cold plate. The hybrid cold-plate further includes a cover plate positioned overtop the internally cooled cold plate and the passive heat-transfer component. The cover plate is further configured to urge the internally cooled cold plate toward the processing unit, or the passive heat-transfer component toward the heat-generating component, or the passive heat-transfer toward the internally cooled cold plate, or a combination thereof;

Some disclosed cooling systems also include one or more of a first thermal interface material positioned between the cover plate and the passive heat-transfer component, a second thermal interface material positioned between the cover plate and the internally cooled cold plate, a third thermal interface material positioned between the passive heat-transfer component and the internally cooled cold plate, a fourth thermal interface material positioned between the passive heat-transfer component and the heat-generating component, and a fifth thermal interface material positioned between the internally cooled cold plate and the processing unit.

The processing unit can include a semiconductor die mounted to a substrate having a plurality of integrated-circuit segments. The internally cooled cold plate can be bonded with the semiconductor die and supported by the substrate as a portion of a distinct, packaged processing component. The passive heat-transfer component and the cover plate can be configured to be assembled with the packaged processing component and combined into the hybrid cold plate after the packaged processing component, and its internally cooled cold plate, has been installed in an electronic device.

The cover plate can define an aperture and the internally cooled cold plate can define a raised portion that extends through the aperture. For example, the raised portion can define a portion of an inlet passage to the internally cooled cold plate, an outlet passage from the internally cooled cold plate, or both.

The internally cooled cold plate can have another thermal interface region configured to be placed into thermal contact with another passive heat-transfer component. The heat-generating component can be a first heat-generating component and the passive heat-transfer component can be a first passive heat-transfer component. The hybrid cold plate can also include a second passive heat-transfer component having a first thermal interface region configured to be placed into thermal contact with the second heat-generating component and a second thermal interface region configured to be placed into thermal contact with the other thermal interface region of the internally cooled cold plate.

According to yet another aspect, methods of assembling an electronic device are disclosed. Such methods include coupling a packaged processing unit with an operable substrate. The packaged processing unit can include an integrated-circuit die and an internally cooled cold plate bonded with a surface of the integrated-circuit die. A passive heat-transfer component can be placed into thermal contact with a heat-generating component positioned adjacent the processing unit and into thermal contact with the internally cooled cold plate. A cover plate can be positioned overtop the internally cooled cold plate and the passive heat-transfer component. The cover plate can be urged toward the operable substrate, and thereby compress the internally cooled cold plate and the passive heat-transfer component together.

The act of placing the passive heat-transfer component into thermal contact with the heat-generating component positioned adjacent the processing unit and into thermal contact with the internally cooled cold plate can include positioning a thermal interface material between the passive heat-transfer component and the heat-generating component positioned adjacent the processing unit or the internally cooled cold plate, or both.

The foregoing and other features and advantages will become more apparent from the following detailed description, which proceeds with reference to the accompanying drawings.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 illustrates a closed liquid-cooling loop.

FIG. 2 illustrates an isometric view of a hybrid cold plate from above.

FIG. 3 illustrates an isometric view of the hybrid cold plate shown in FIG. 2 with the spring-loaded fasteners shown in FIG. 2 removed.

FIG. 4 illustrates an isometric view of the hybrid cold plate shown in FIG. 2 from below.

FIG. 5 illustrates an isometric view of the cover plate (e.g., made from a lightweight, thermally conductive material, such as, for example, aluminum) shown in FIGS. 2, 3 and 4 from above.

FIG. 6 illustrates another isometric view of the hybrid cold plate shown in FIG. 2 from below.

FIG. 7 illustrates an isometric view of the thermally conductive cover plate shown in FIG. 5 from below.

FIG. 8 illustrates an isometric view of a portion of the hybrid cold plate, as in FIG. 6, with the internally cooled cold plate and thermal interface materials removed to reveal portions of the passive heat-transfer components obscured in FIG. 6.

FIG. 9 illustrates an isometric view of the hybrid cold plate as in FIG. 3 with the thermally conductive cover plate removed to reveal portions of the internally cooled cold plate and the passive heat-transfer components, as well as thermal interface materials, obscured in FIG. 3.

FIG. 10 illustrates an isometric view of the hybrid cold plate as in FIG. 6 with the thermally conductive cover plate removed.

FIG. 11 illustrates an isometric view of the hybrid cold plate as in FIG. 9, with the thermal interface material at the interface between the thermally conductive cover plate and one of the passive heat-transfer components removed, revealing an upper surface of the passive heat-transfer component.

FIG. 12 illustrates an isometric view of the hybrid cold plate as in FIG. 11, with the passive heat-transfer component partially revealed in FIG. 11 removed, revealing the thermal interface material at the interface between an upper surface of the internally cooled cold plate and an underside of the removed passive heat-transfer component.

FIG. 13 illustrates an isometric view of a longitudinal cross-section taken along a longitudinal mid-plane of the hybrid cold plate shown in FIG. 2.

FIG. 14 illustrates a side elevation view of the longitudinal cross-section in FIG. 13.

FIG. 15 illustrates an isometric view of a transverse cross-section taken along a transverse mid-plane of the hybrid cold plate shown in FIG. 2.

FIG. 16 illustrates a side elevation view of the longitudinal cross-section in FIG. 15.

FIG. 17 illustrates an isometric view from above the internally cooled cold plate shown in FIGS. 2 and 3.

FIG. 18 illustrates a partial cross-section taken along a horizontal plane generally parallel with an underside heat-transfer surface (e.g., shown in FIGS. 4 and 6) of the internally cooled cold plate shown in FIG. 17.

FIG. 19 illustrates another partial cross-section taken along a horizontal plane proximal to (relative to the underside heat-transfer surface) and generally parallel with the horizontal plane shown in FIG. 18.

FIG. 20 illustrates another partial cross-section taken along a horizontal plane proximal to (relative to the underside heat-transfer surface) and generally parallel with the horizontal planes shown in FIGS. 18 and 19.

FIG. 21 illustrates another partial cross-section taken along a horizontal plane proximal to (relative to the underside heat-transfer surface) and generally parallel with the horizontal planes shown in FIGS. 18, 19 and 20.

FIG. 22 shows a relative temperature profile throughout the passive heat-transfer component that results without benefit of the augmented heat transfer provided by the thermally conductive cover plate shown in FIGS. 5 and 7.

FIG. 23 shows a relative temperature profile throughout the thermally conductive cover plate shown in FIGS. 5 and 7.

FIG. 24 shows representative heat sources used to generate the relative temperature profiles shown in FIGS. 22 and 23.

FIG. 25 schematically illustrates an internally cooled cold plate bonded with a plurality of bare dice (e.g., chiplets) mounted to a substrate having a plurality of integrated-circuit segments (not shown) as a portion of a distinct, packaged processing component.

### DETAILED DESCRIPTION

The following describes various principles related to hybrid cooling systems. Such hybrid cooling systems can combine an active closed cooling circuit (or loop) and a passive heat-transfer component to cool a plurality of heat-generating components. Active closed cooling circuits are described, for example, in U.S. Pat. No. 9,496,200, issued Nov. 15, 2016, U.S. Pat. No. 9,453,691, issued Sep. 27, 2016, the contents of which patents are hereby incorporated by reference to the same extent as if reproduced herein in full, for all purposes. Active closed cooling circuits also are described in co-pending U.S. patent application Ser. No. 18/297,561, filed on Apr. 7, 2023. Such closed cooling circuits can incorporate one or more internally cooled cold plates to cool a heat-generating component, e.g., as described, for example, in U.S. Pat. No. 8,746,330, issued Jun. 10, 2014, U.S. Pat. No. 11,725,886, issued Aug. 15, 2023, and co-pending U.S. Patent Application Ser. No. 63/533,847, filed Aug. 21, 2023.

Passive two-phase heat-transfer components are described, by way of example, in U.S. Patent Application Ser. No. 63/526,917, filed on Jul. 14, 2023. As the passive, two-phase cold plates thermally couple a plurality of heat-generating components (e.g., DRAMS) with a liquid-cooled condenser block in U.S. Patent Application Ser. No. 63/526,917, disclosed hybrid cold plates incorporate one or more passive heat-transfer components (e.g., a thermally conductive plate or sheet or a vapor chamber, heat pipe, or other passive two-phase heat-transfer component) that thermally couples one or more heat-generating components (e.g., heat-generating power components, chiplets, DRAMs, etc.) with an internally cooled cold plate that is itself thermally coupled with one or more other heat-generating components (e.g., a processing unit, a chipset, a multi-chip module, etc.).

When used to cool a plurality of heat-generating components, disclosed hybrid cold plates provide one or more advantages compared to using an internally cooled cold plate to directly cool the plurality of heat-generating components. For example, even if the plurality of heat-generating components (which can include a higher-power component, such as, for example, a central processing unit, a graphics processing unit or a communication bridge (or other chipset)) are positioned in relatively close proximity with each other, the “foot print” (e.g., circuit-board area) occupied by the plurality of heat-generating components typically is significantly larger than the “foot print” occupied by a single (even if higher-power) heat-generating component. Thus, simply enlarging an internally cooled cold plate to overlie and contact each in the plurality of heat-generating components will result in a significantly larger, and more massive, internally cooled cold plate compared to (1) an internally cooled cold plate designed to cool just one of the plurality of heat-generating components; or (2) a disclosed hybrid cold plate. Accordingly, retaining and supporting such an enlarged internally cooled cold plate will require significantly larger and more robust structural retention devices compared to those required to retain (1) an internally cooled cold plate designed to cool just one of the plurality of heat-generating components; or (2) a disclosed hybrid cold plate. Further, such an enlarged internally cooled cold plate typically would have a relatively stiff base surface overlying the plurality of heat-generating components and thus would have limited capacity to absorb dimensional variations, e.g., in height of the plurality of heat-generating components, that arise from manufacturing variations and dimensional tolerances. By contrast, some disclosed passive heat-transfer components are less stiff than a base of an internally cooled cold plate, and in some cases are sufficiently flexible to absorb up to several millimeters of dimensional variation (e.g., in a height direction). Indeed, some disclosed hybrid cold plates can cool a plurality of heat-generating components without requiring a significantly higher compressive load applied between the substrate to which the heat-generating components are mounted and the cold plate compared to the compressive load applied between a typical motherboard and an internally cooled cold plate.

Some aspects of disclosed principles pertain to internally cooled cold plates (whether single-phase or two-phase cold plates) suitable for directly cooling one or more heat-generating components (e.g., by being in direct thermal contact with the one or more heat-generating components, e.g., mounted to a lid (sometimes referred to in the art as an “integrated heat spreader” or “IHS”) positioned overtop a die with or without an intervening thermal interface material, or mounted to a bare die with or without an intervening thermal interface material. (Unless expressly stated otherwise, or unless the context requires a different conclusion, reference herein to an “internally cooled cold plate” refers to single-phase cold plates and two-phase cold plates.) Some aspects of disclosed principles pertain to internally cooled cold plates for indirectly cooling one or more other heat-generating components, e.g., by being indirectly thermally coupled with the one or more other heat-generating components via an intervening passive heat-transfer component. Some aspects of disclosed principles pertain to combining an internally cooled cold plate with one or more passive heat-transfer components to define a hybrid cold plate. Some aspects of disclosed principles pertain to integrating several components with each other to define a hybrid cold plate suitable for meeting cooling demands of a plurality of heat-generating components and for accommodating dimensional variations (e.g., variations in height, which is sometimes referred to in the art as a “tolerance stack up”) across the plurality of heat-generating components, as well as for mounting to a motherboard or other substrate to which the plurality of heat-generating components are mounted.

That said, descriptions herein of specific component and apparatus configurations, and combinations of method acts, are but particular examples drawn on as being convenient, illustrative examples of disclosed principles. One or more of the disclosed principles can be incorporated in various other configurations and systems to achieve any of a variety of desired characteristics corresponding to such other configurations and systems.

Thus, systems having attributes that are different from those specific examples discussed herein can embody one or more presently disclosed principles and can be used in applications not described herein in detail. Accordingly, such alternative embodiments also fall within the scope of this disclosure.

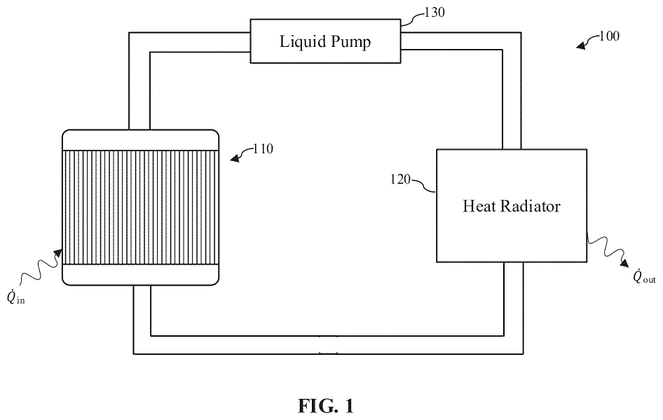

As noted above, FIG. 1 schematically illustrates a closed liquid-cooling loop 100. The liquid-cooling loop 100 includes a heat exchanger 110 that removes heat, \dot{Q}ᵢₙ, from a component (not shown) that generates heat while operating. However, the heat exchanger 110 need not be limited to cooling a single electronic component that dissipates heat while operating. For example, some electronic devices, e.g., servers (alone or installed in a rack, which itself may be installed in a data center), desktop computers, power electronics devices, etc., include a multi-chip module. And, some electronic devices include more than one such multi-chip module. Further, some multi-chip modules require rates of cooling beyond that which air cooling alone can achieve within some electronic devices. Accordingly, some electronic devices require augmented cooling for some or all components mounted to, for example, a multi-chip module.

Accordingly, the heat exchanger 110 shown in FIG. 1 can be configured to cool the heat-generating components of one or more multi-chip modules, or to cool another plurality of heat-generating components, e.g., mounted to a motherboard or other substrate. For example, the heat exchanger 110 can receive heat directly or indirectly from each of a plurality of components and transfer the heat to a coolant passing through the heat exchanger. As described above in connection with FIG. 1, the coolant can flow from the heat exchanger 110 to a heat radiator 120, carrying the received heat to the radiator. As the heated coolant flows through the heat radiator, heat, \dot{Q}ₒᵤₜ, can be transferred to another cooling medium, cooling the coolant. The cooled coolant can again pass through the heat exchanger 110 to remove further heat dissipated by the heat-generating components of the one or more multi-chip modules (and/or other components). Additionally, one or more pumps 130 can urge the coolant throughout the components of the cooling loop 100.

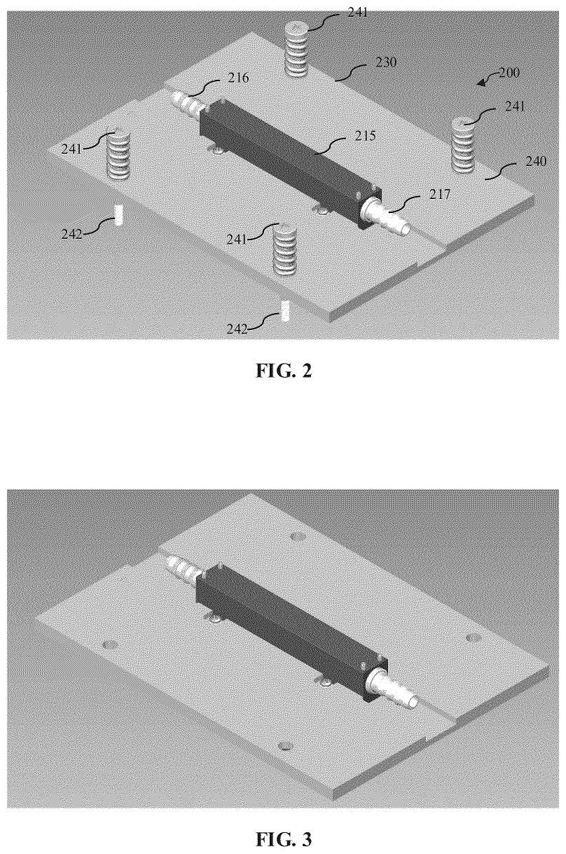

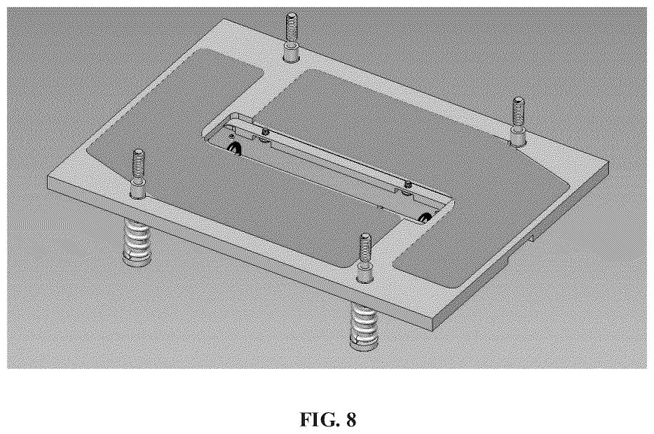

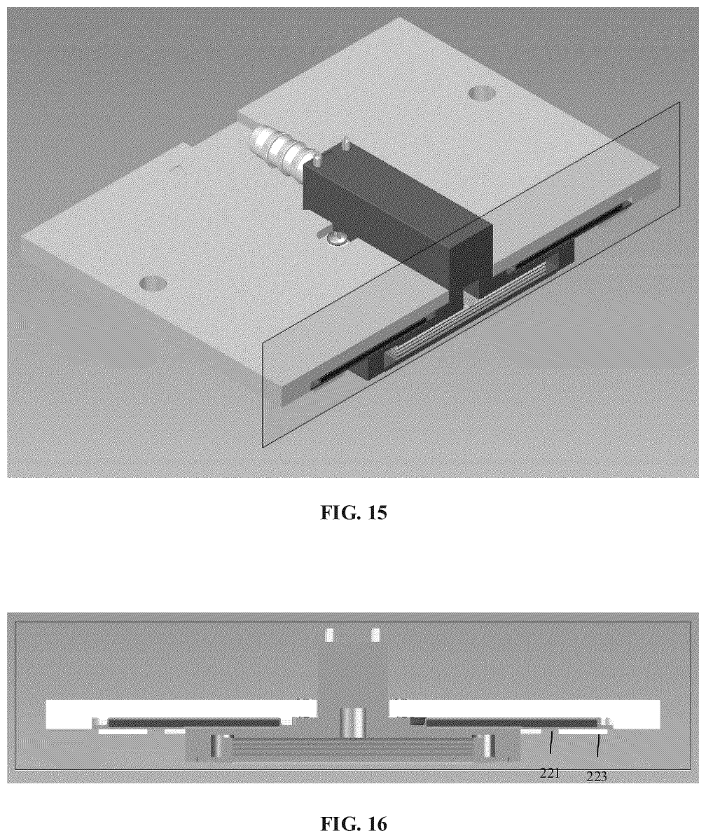

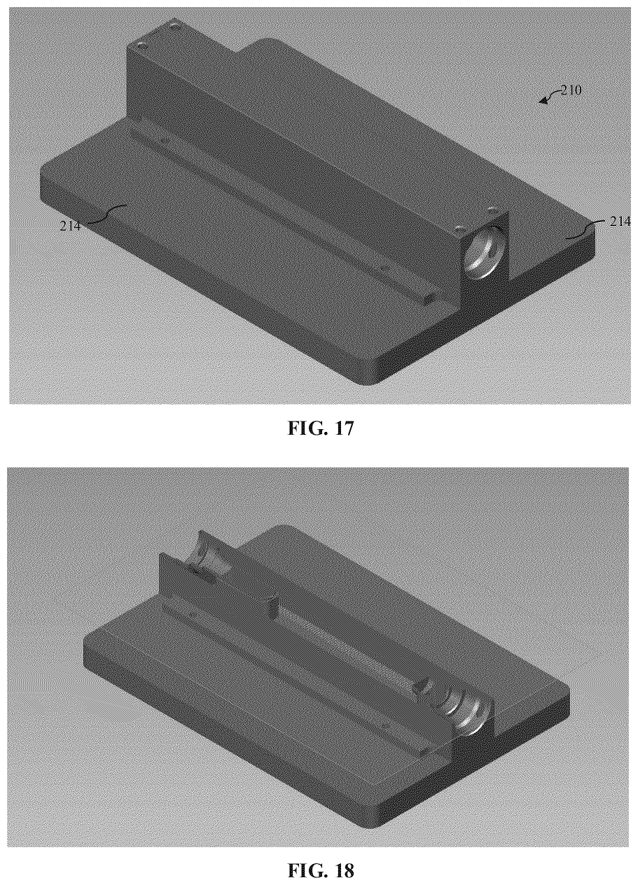

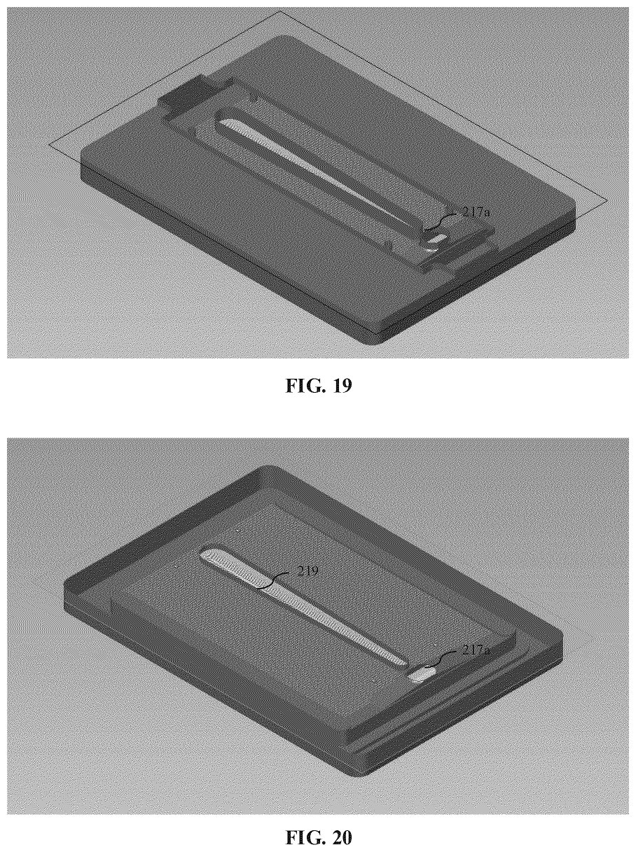

Referring now to FIGS. 2 through 24, principles pertaining to the heat exchanger 110 will be described in context of hybrid cold plates that combine an internally cooled cold plate with one or more passive heat-transfer components. The internally cooled cold plate can be mounted or mountable with a packaged semiconductor. For example, some packaged semiconductors incorporate a lid or IHS positioned overtop the active (e.g., heat-generating) die, while other packaged semiconductors omit such a lid or IHS. Some packaged semiconductors incorporate a plurality of dice (sometimes referred to in the art as “chiplets”) and a lid or an IHS overlies one or more (or all) of the chiplets. In other embodiments, no lid or IHS overlies any of the chiplets.

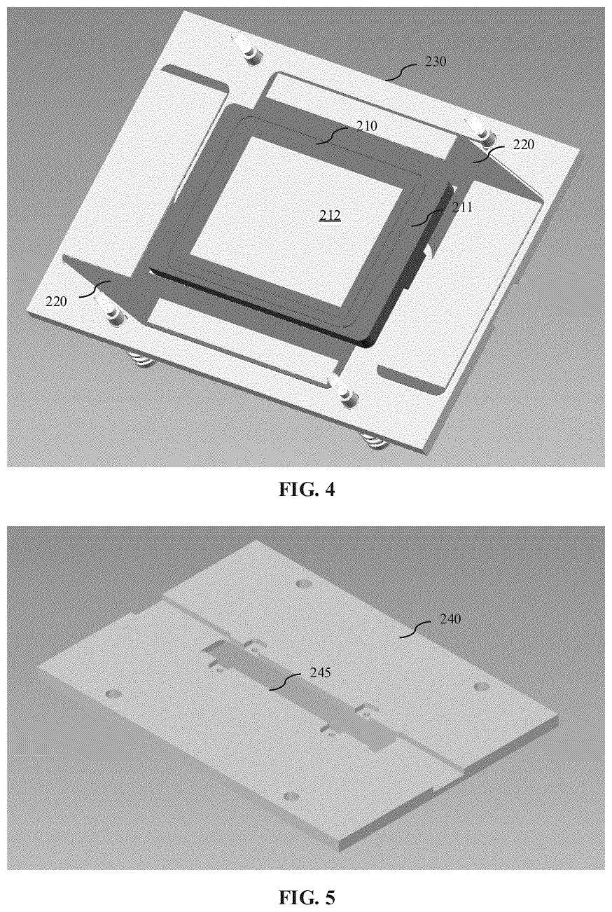

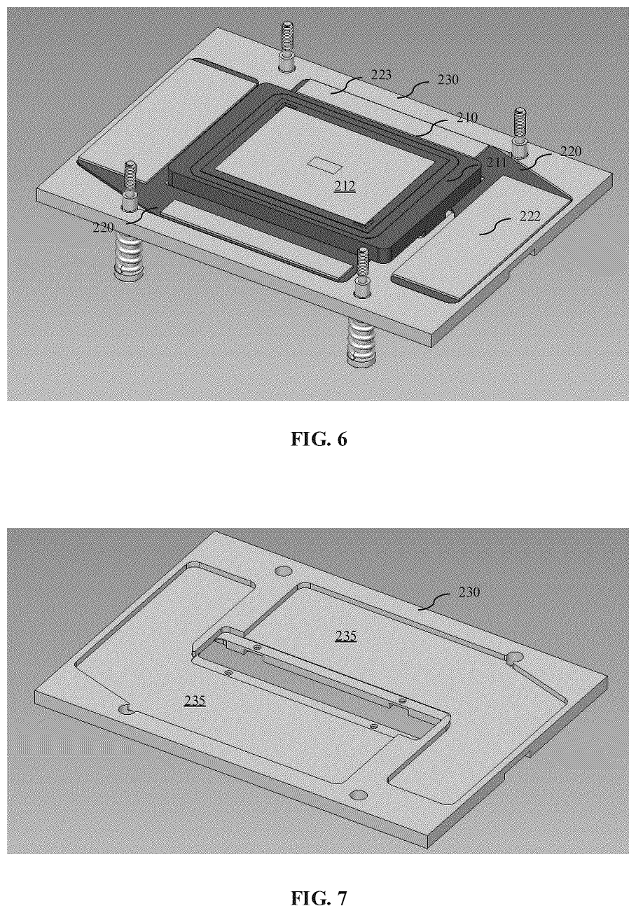

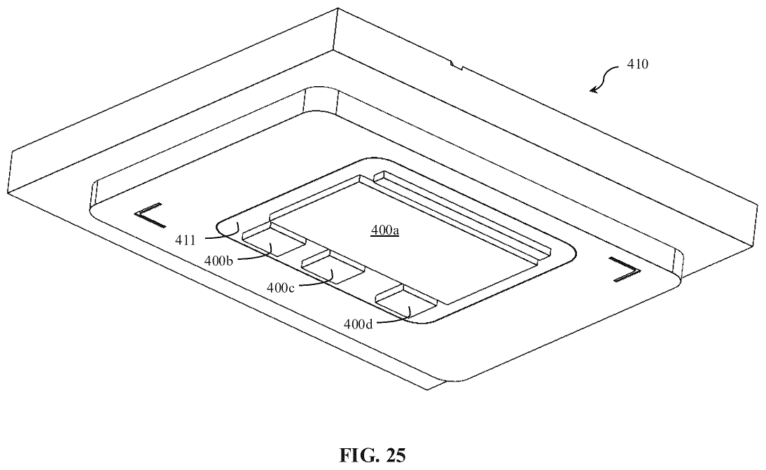

FIG. 2 shows a hybrid cold plate 200 having an internally cooled cold plate 210 and a pair of passive heat-transfer components 220 (FIGS. 4 and 6). Each of the internally cooled cold plate 210 and the pair of passive heat-transfer components 220 is configured to be placed into thermal contact (e.g., with or without an intervening thermal interface material) with one or more corresponding heat-generating components, e.g., as schematically indicated by the heat sources 300a (e.g., a processing unit), 300b (e.g., power electronics components, such as, for example, voltage regulation components), 300c (e.g., DRAMs or communication bridges, or other chipsets) shown in FIG. 24.

The internally cooled cold plate 210 defines a base region 211. The base region 211 can be placed in thermal contact with a corresponding region of a heat-generating component (e.g., represented by the heat source 300a) to conductively receive heat generated by the heat-generating component. A thermal interface material 212 can be disposed between the base region 211 of the internally cooled cold plate 210 and the heat-generating component to facilitate conductive heat transfer across the interface between the internally cooled cold plate 210 and the heat-generating component. The heat-generating component has a lid or an IHS overlying an active component and the thermal interface material 212 can be disposed between the base region 211 of the internally cooled cold plate 210 and the lid or IHS. In other embodiments, no lid or IHS overlies an active component and the thermal interface material 212 can be disposed between the base region 211 of the internally cooled cold plate 210 and the active component (or a backside of the die thereof).

Similarly, the passive heat-transfer components 220 define respective base regions 221 (FIGS. 14 and 16). Each respective base region 221 can be placed in thermal contact with a corresponding region of one or more heat-generating components (e.g., represented by the heat sources 300b, 300c in FIG. 24) to conductively receive heat generated by the one or more heat-generating components. A thermal interface material 222, 223 can be disposed between the base region 221 of the passive heat-transfer components 220 and the respective one or more heat-generating components (e.g., sources 300b, 300c) to facilitate conductive heat transfer across the interface between the passive heat-transfer components 220 and the one or more heat-generating components.

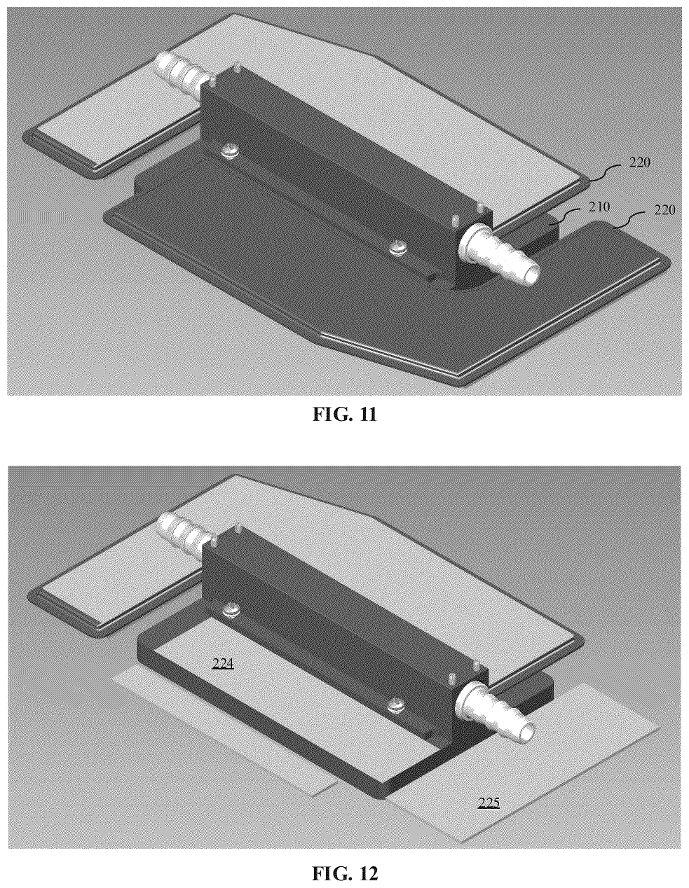

The internally cooled cold plate 210 also defines a top region 214 (FIG. 17). The top region 214 of the internally cooled cold plate can be placed in thermal contact with a corresponding portion of the base region 221 of one or both of the passive heat-transfer components 220. Such thermal contact between the internally cooled cold plate 210 and one or both of the passive heat-transfer components 220 can transfer heat conveyed by the passive heat-transfer component from the one or more heat-generating components (e.g., represented by the heat sources 300b, 300c in FIG. 24) to the internally cooled cold plate, and thus to the coolant passing therethrough. As with other thermal interfaces described herein, a thermal interface material 224 (FIG. 12) can be disposed between the base region 221 of one or both of the passive heat-transfer components 220 and the top region 214 of the internally cooled cold plate 210 to facilitate conductive heat transfer across the interface between the passive heat-transfer component 220 and the internally cooled cold plate 210. In some embodiments, one or more of the passive heat-transfer components 220 is a vapor chamber device having one or more condensing regions positioned adjacent the top region 214 of the internally cooled cold plate 210 and one or more evaporating regions positioned adjacent one or more of the heat generating components (e.g., represented by the heat sources 300b, 300c in FIG. 24). In some embodiments, one or more of the passive heat-transfer components 220 is a heat pipe having a condensing region positioned adjacent the top region 214 and an evaporating region spanning across one or more of the heat generating components. In some embodiments, one or more of the passive heat-transfer components 220 is a plate or other member made of one or more thermally conductive materials, e.g., an alloy of copper or aluminum.

In some embodiments, the lid or IHS of a packaged semiconductor physically incorporates an internal heat-transfer chamber that receives a liquid coolant or a refrigerant. In such embodiments, the lid or IHS of the packaged semiconductor includes an internally cooled cold plate. In such embodiments, for example, a semiconductor device manufacturer can produce the packaged semiconductor and mount the internally cooled cold plate to the die, similar in some respects to how semiconductor device manufacturers currently attach the lid or IHS to the die. However, unlike known lids and IHS embodiments that rely on conduction heat transfer to spread heat through the lid or IHS, and embodiment as shown in FIG. 25 can incorporate an internally cooled cold plate 410 in a device package. For example, in FIG. 25, the internally cooled cold plate 410 is configured as a lid or IHS. In FIG. 25, the cold plate 410 defines a heat-transfer surface 411 bonded with a plurality of dice 400a, 400b, 400c, 400d. As the dice operate and generate heat, the heat-transfer surface 411 conducts heat from the dice to the coolant or refrigerant passing through the internal heat-transfer chamber of the internally cooled cold plate 410 as described herein in relation to the cold plate 210. However, embodiments as in FIG. 25 eliminate a thermal interface (and the corresponding thermal resistance) between the conventional lid or IHS and the internally cooled cold plate (e.g., eliminating an interface between the dice and the base of the cold plate). Eliminating that thermal interface can reduce die temperatures by as much as 15° C., such as, for example, between about 10° C. and about 15° C. With such embodiments, a system integrator can place the corresponding portion of the base region 221 of one or both of the passive heat-transfer components 220 into thermal contact with a top region of the internally cooled cold plate 410 (e.g., analogous to the top region 214 of the cold plate 210).

Partitioning the hybrid cold plate between a package-level component (e.g., the internally cooled cold plate 410 incorporated in a package for the operable dice) and board- or system-level components (e.g., the passive heat-transfer components 220 and the cover plate 230) can yield improved cooling performance while maintaining historical ease of system assembly by eliminating a thermal-interface between the dice and the internally cooled cold plate 410. For example, a device manufacturer can produce a packaged semiconductor that places the internally cooled cold plate 410 into direct thermal contact with the die. The internally cooled cold plate 410 can incorporate thermal-interface features (e.g., analogous to top region 214) suited for thermally coupling one or more passive heat-transfer components 220 with the internally cooled cold plate 410 to remove heat from adjacent heat-generating components (e.g., VR components).

FIGS. 2, 3, 6, 7 and 8 depict several aspects of an exemplary embodiment of a cover plate for a hybrid cold plate. In FIG. 2, a plurality of fasteners 241 extend through the cover plate 230. Each fastener includes a lug 242 that can extend through a corresponding hole defined by, for example, a motherboard (or other substrate to which the heat-generating component(s) are mounted). A coil spring (or a plurality of nested coil springs) can extend around the lug adjacent one face of the cover plate 230. A nut or other complementary fastening component can engage with each respective lug 242 and can urge against the motherboard (or other substrate), placing the respective lug in tension, which tends to compress the coil spring (or the plurality of nested coil springs) to urge the cover plate 230 toward the motherboard (or other substrate). Nested coil springs may be particularly advantageous when available vertical displacement is limited and compression forces are high. For example, a pair of nested springs that have matching spring constants need only be compressed half as far to apply the same compressive force as compared just one of the nested springs. (Of course, nested springs might have different spring constants, so the displacement required to achieve a given compressive load may not be exactly one-half as compared to the displacement required for one or the other of the pair of nested springs.). Additionally, it should be noted that the use of nested springs for retaining cold plates and other heat-transfer components is not limited solely to the cold plate and other heat-transfer components disclosed herein, but rather may be applied generally to any known or hereafter developed cold plate or heat-transfer component to be placed into a selected measure of compression against another device, package or heat-transfer surface.

As the cover plate 230 urges toward the motherboard, it can urge against the passive heat-transfer components 220, the internally cooled cold plate 210, or both. As the cover plate 230 urges against the passive heat-transfer components 220, the interface between cover plate 230 and the passive heat-transfer components is compressed, further urging the passive heat-transfer components 220 against the top region of the internally cooled cold plate 210.

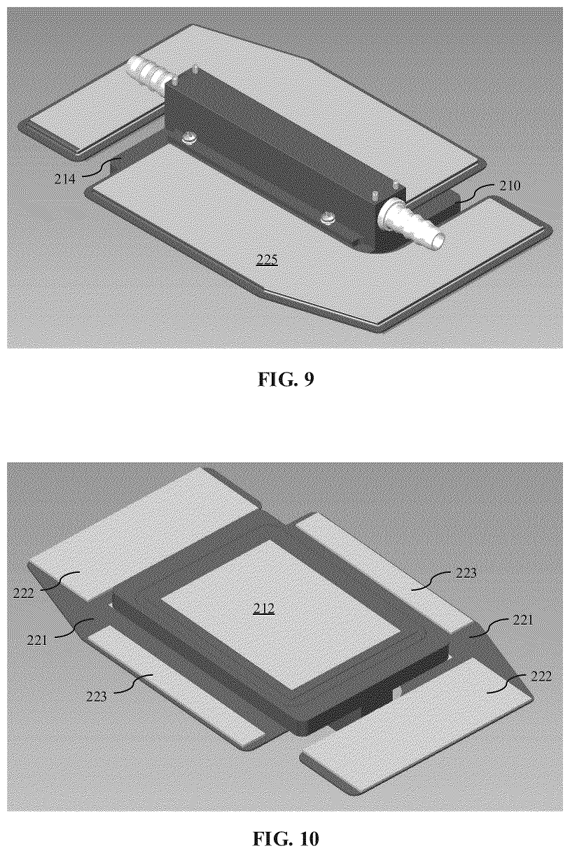

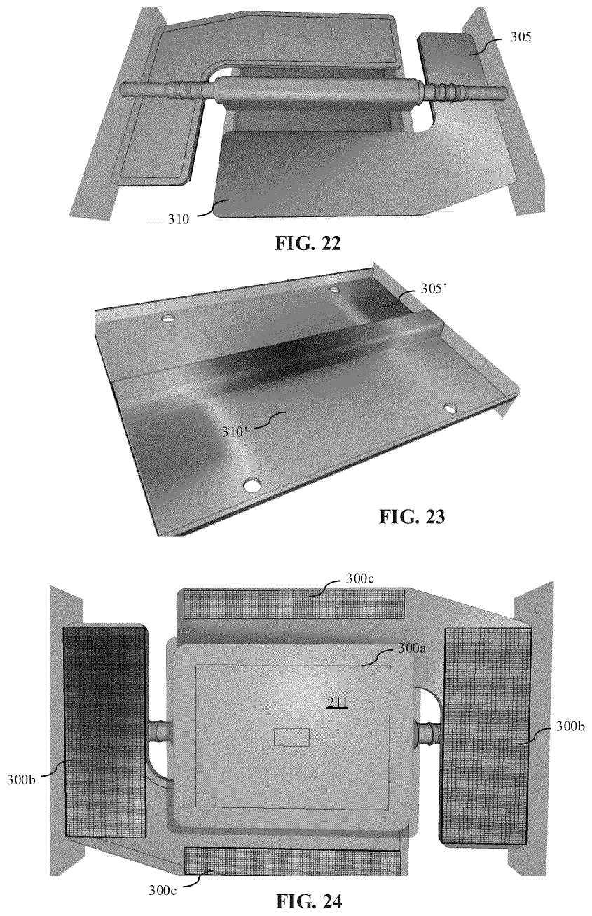

In some embodiments, a thermal interface material 225 (FIG. 9) is applied at the interface between cover plate 230 and the passive heat-transfer components 220 to enhance conductive heat transfer between the cover plate 230 and the passive heat-transfer components 220, providing a parallel heat-transfer path along which heat received by the passive heat-transfer components 220 from, e.g., the heat-generating components represented by the heat source 330b, can transfer to the internally cooled cold plate. A comparison of the temperature gradients shown in FIG. 22 and FIG. 23 reveals benefits of such a parallel heat-transfer path. For example, a difference in temperature between the region 305 and the region 310 in FIG. 22 (which lacks a thermally conductive cover plate 230) is significantly higher than a difference in temperature between the region 305′ and the region 310′ in FIG. 23 (which includes a thermally conductive cover plate 230).

Further, as the cover plate 230 urges against the passive heat-transfer components 220, the passive heat-transfer components 220 also urge against the one or more heat-generating components, e.g., represented by the heat sources 300b, 300c in FIG. 24), enhancing thermal contact between the passive heat-transfer components 220 and the one or more heat-generating components. As with the other interfaces described above, a thermal interface material 222, 223 can be positioned within the interface between the passive heat-transfer components 220 and the one or more heat-generating components to further enhance the thermal contact therebetween.

Similarly, as the cover plate 230 urges against the passive heat-transfer components 220, the passive heat-transfer components 220 also urge against the internally cooled cold plate 210, enhancing thermal contact between the passive heat-transfer components 220 and the internally cooled cold plate 210. As with the other interfaces described above, a thermal interface material 224 can be positioned within the interface between the passive heat-transfer components 220 and the internally cooled cold plate 210 to further enhance the thermal contact therebetween.

As the passive heat-transfer components 220 urge against the internally cooled cold plate 210, the internally cooled cold plate also urges against one or more heat-generating components (e.g., represented by the heat source 300a in FIG. 24), enhancing thermal contact between the internally cooled cold plate 210 and the corresponding one or more heat-generating components. As with the other interfaces described above, a thermal interface material 212 can be positioned within the interface between the internally cooled cold plate 210 and the corresponding one or more heat-generating components to further enhance the thermal contact therebetween.

Accordingly, in addition to simply retaining the hybrid cold plate 200 relative to a mother board or other substrate to which the one or more heat-generating components are mounted, a cover plate 230 as described can enhance conductive heat transfer from the heat-generating components to the internally cooled cold plate 210 by compressing the various thermal interfaces within the hybrid cold plate assembly, as well as by providing a complementary conductive heat transfer path (e.g., a so-called “thermal bridge”) from a heat-generating component positioned distally away from, for example, a thermal interface between the internally cooled cold plate 210 and one or more passive heat-transfer components 220. ‘

As shown in FIG. 2, a fluid interface portion 215 of the internally cooled cold plate 210 can extend through an aperture 245 defined by the cover plate 240. The fluid interface portion 215 can provide an inlet connector 216 and an outlet connector 217 for fluidly connecting the cold plate 210 within a cooling loop, e.g., similar to the connection of the heat exchanger 110 within the cooling loop 100 in FIG. 1.

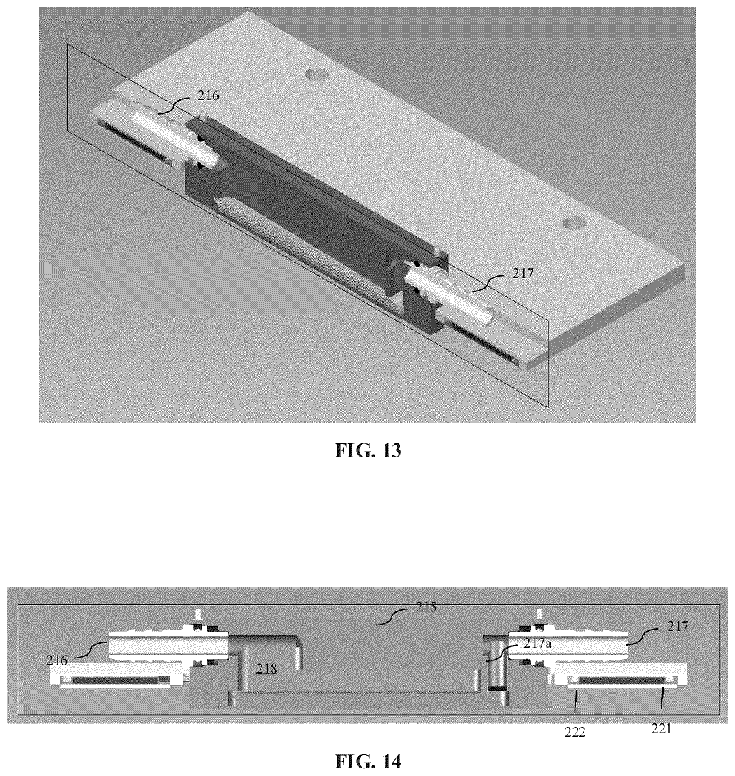

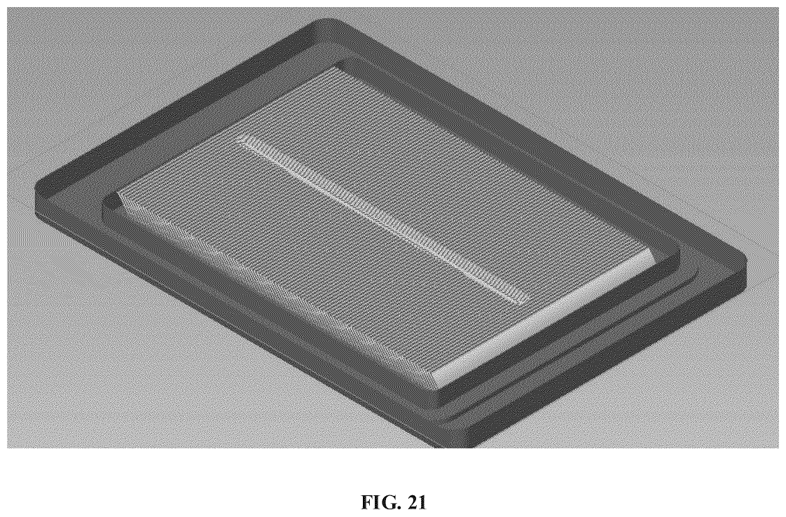

As FIGS. 13 through 21 show, a flow path of coolant from the inlet connector 216 to the outlet connector 217 through the internally cooled cold plate 210 can be similar to a split-flow path described, for example, in U.S. Pat. No. 8,746,330. For example, coolant can enter the cold plate 210 through the inlet connector 216, pass through an inlet header 218 before passing through an inlet opening 219 that extends transversely overtop a plurality of microchannels (FIG. 21). As the coolant passes through the inlet opening 219, it can split into opposed subflows within each microchannel, with each subflow extending within the microchannel toward the microchannel ends, which flank the inlet opening. The subflows can exit the microchannels and flow into respective portions of an outlet header before passing into a segment 217a of the outlet passage that leads to the outlet connector 217. In an embodiment of the internally cooled cold plate 210, a seal member as described in the '330 patent is omitted and, instead, a compressive interface between the housing and the fins defining the microchannels inhibits or prevents the coolant from bypassing the microchannels. A cold plate that incorporates such a compressive interface is described, by way of example, in co-pending U.S. Patent Application No. 63/533,847, filed on Aug. 21, 2023. In some embodiments, the flow direction through the cold plate 210 is reversed from what is described above. For example, a flow path of coolant can enter the connector 217, bifurcate in the segment 217a of the passage before entering the opposed header regions adjacent the microchannel ends. The coolant can then enter the opposed microchannel ends and flow inwardly toward a center region of the microchannels and exhaust from the microchannels through the opening 219 into the header 218, and exhaust from the cold plate 210 through the connector 216.

As FIGS. 6 and 7 show, some embodiments of the cover plate 230 define a recess 235 complementary with and configured to receive a passive heat-transfer component 220. A depth of the recess 235 can correspond, for example, to a vertical (relative to the motherboard) thickness of the passive heat-transfer component 220, the vertical height of each heat-generating component to be cooled by the passive heat-transfer component 220, and a vertical height of the top region 214 of the internally cooled cold plate 210.

Thermal interface materials described herein can include thermal greases, thermal gap pads, thermal gels, thermal interface foils, etc. To facilitate variability in vertical height, e.g., from aggregated manufacturing tolerances, some thermal interface materials will desirably be able to compress to a greater degree than other thermal interfaces. Moreover, some disclosed passive heat-transfer components 220 can physically deform by up to 5 mm or more to accommodate such dimensional variation without degrading thermal performance of disclosed hybrid cold plates.

Referring again to the schematic illustration in FIG. 1, a hybrid cooler as just described can be substituted for the heat exchanger 110. Alternatively, one or more hybrid coolers can be added to a cooling loop of the type depicted in FIG. 1. For example, the heat exchanger 110 shown in FIG. 1 may be placed in thermal contact with a processing component, and one or more hybrid coolers 200 as described herein can be fluidically coupled (in series or in parallel) with the heat exchanger 110. On reviewing this disclosure, a person of ordinary skill in the art will understand and appreciate the various modifications to fluid connections, pumping resources, and radiator configurations that such alternative arrangements could or would require in order to urge a sufficient flow of coolant through each heat exchanger/heat-exchanger assembly in a given cooling loop, as well as to reject absorbed heat from the coolant to another cooling medium.

Such cooling systems also can include a heat radiator configured to reject heat from the liquid coolant to another medium as the liquid coolant passes through the heat exchanger, generally as described above in connection with FIG. 1. Such cooling systems also include a pump configured to urge the liquid coolant throughout a closed loop, including the liquid-cooled condenser block and the heat exchanger.

A cooling system as just described can be installed in or on an electronic device to cool a multi-chip module alone or in combination with other heat-generating components (e.g., processing units). And, a typical memory module, for example, may have between four and forty, or more, active electronic components (e.g., DRAMs), as well as additional heat-dissipating components like power delivery devices, memory controllers, EEPROMs, etc. Moreover, a given electronic device may have an array of multi-chip modules installed, with each module being cooled by a cooling system as described above. For example, such an array of multi-chip modules may include one or more multi-chip modules, or one or more pairs of multi-chip modules.

Some embodiments described herein can be used to cool one or more multi-chip modules, each having a plurality of active electronic components that generate heat while operating. Nonetheless, the previous description is provided to enable a person skilled in the art to make or use embodiments of the disclosed principles. Embodiments other than those described above in detail are contemplated based on the principles disclosed herein, together with any attendant changes in configurations of the respective apparatus or changes in order of method acts described herein, without departing from the spirit or scope of this disclosure. Various modifications to the examples described herein will be readily apparent to those skilled in the art.

For example, concepts described herein can be used to cool a plurality of other types of heat-generating components that are combined into a functional module (e.g., as with a DIMM or another multichip module, e.g., a processing unit that includes one or more processing cores or chips, together with one or more voltage regulating components (so-called “VR components”) or other modules that include, for example, a so-called intermediate bus converter (IBC). For example, a passive, two-phase cold plate (or other passive heat-transfer component) can span across a plurality of such alternative components, even when the components have different heights from each other relative to the substrate to which they are mounted (e.g., by using concepts described herein, such as, for example, deforming a passive heat-transfer component or a compressible thermal interface material).

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface, and the object remains the same. As used herein, “and/or” means “and” or “or”, as well as “and” and “or.” Moreover, all patent and non-patent literature cited herein is hereby incorporated by reference in its entirety for all purposes.

And, those of ordinary skill in the art will appreciate that the exemplary embodiments disclosed herein can be adapted to various configurations and/or uses without departing from the disclosed principles. Applying the principles disclosed herein, it is possible to provide a wide variety of cooling devices for multi-chip modules, and related methods and systems to remove waste heat from such multi-chip modules. For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of cooling devices, and related methods and systems that can be devised using the various concepts described herein.

Moreover, nothing disclosed herein is intended to be dedicated to the public regardless of whether such disclosure is explicitly recited in the claims. No claim feature is to be construed under the provisions of 35 USC 112(f), unless the feature is expressly recited using the phrase “means for” or “step for”.

Reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, including in the following claims.

I currently claim:

1. A hybrid cold plate, comprising:
a passive heat-transfer component defining a first thermal-interface region configured to be placed into thermal contact with a heat-generating component and a second thermal-interface region configured to be placed into thermal contact with a corresponding surface of an internally cooled cold plate; and
a cover plate configured to overlie the passive heat-transfer component and to urge the passive heat-transfer component in compression against the heat-generating component, the surface of the internally cooled cold plate, or both.

2. The hybrid cold-plate according to claim 1, wherein the cover plate defines a first major surface and an opposed second major surface, wherein the second major surface defines a recessed region configured to receive a portion of the passive heat-transfer component therein when the passive heat-transfer component is placed into thermal contact with the heat-generating component, the internally cooled cold plate, or both.

3. The hybrid cold-plate according to claim 1, wherein, when the passive heat-transfer component is placed into thermal contact with the heat-generating component, the internally cooled cold plate, or both, the passive heat-transfer component is positioned between the heat-generating component and the cover plate.

4. The hybrid cold-plate according to claim 1, wherein a portion of the cover plate configured to overlie the passive heat-transfer component is formed of a thermally conductive metallic alloy.

5. The hybrid cold-plate according to claim 5, further comprising a thermal interface material positioned between the cover plate and the passive heat-transfer component, between the passive heat-transfer component and the heat generating component, or both.

6. The hybrid cold-plate according to claim 1, wherein the cover plate comprises a unitary construction.

7. The hybrid cold-plate according to claim 1, wherein the cover plate defines an aperture configured to receive a raised portion of the internally cooled cold plate.

8. The hybrid cold plate according to claim 1, wherein the passive heat-transfer component is a first passive heat-transfer component configured to be placed into thermal contact with a first heat-generating component, the hybrid cold plate further comprising a second passive heat-transfer component configured to be placed into thermal contact with a second heat-generating component.

9. The hybrid cold plate according to claim 1, wherein the first thermal-interface region of the passive heat-transfer component is an evaporator region and wherein the second thermal-interface region of the passive heat-transfer component is a condenser region.

10. The hybrid cold plate according to claim 1, wherein the passive heat-transfer component is configured to transfer heat from the heat generating component to the internally cooled cold plate.

11. The hybrid cold-plate according to claim 1, wherein the heat-generating component is a first heat-generating component, wherein the hybrid cold-plate further comprises the internally cooled cold plate, wherein the internally cooled cold plate defines a first heat-transfer surface configured to be placed into thermal contact with a corresponding heat-transfer surface of a second heat-generating component, and wherein the internally cooled cold plate defines a second heat-transfer surface configured to be placed into thermal contact with the second thermal-interface region of the cover plate.

12. The hybrid cold-plate according to claim 11, further comprising a thermal interface material positioned between the first heat-transfer surface of the heat-transfer of the second heat-generating component.

13. The hybrid cold-plate according to claim 11, wherein the heat-generating component comprises a bare die, wherein the internally cooled cold plate is bonded with the bare die.

14. A cooling system configured to cool a processing unit and a heat-generating component positioned adjacent the processing unit, the cooling system comprising:
a hybrid cold-plate configured to cool the processing unit and the heat-generating component by transferring heat to a coolant, the hybrid cold-plate comprising:
an internally cooled cold plate having a first thermal interface region configured to be placed into thermal contact with the processing unit and a second thermal interface region configured to be placed into thermal contact with a passive heat-transfer component;
a passive heat-transfer component having a first thermal interface region configured to be placed into thermal contact with the heat-generating component and a second thermal interface region configured to be placed into thermal contact with the second thermal interface region of the internally cooled cold plate; and
a cover plate positioned overtop the internally cooled cold plate and the passive heat-transfer component, the cover plate further configured to urge the internally cooled cold plate toward the processing unit, or the passive heat-transfer component toward the heat-generating component, or the passive heat-transfer toward the internally cooled cold plate, or a combination thereof;
the cooling system further comprising a heat exchanger configured to reject the heat from the coolant to another medium.

15. The cooling system according to claim 14, further comprising one or more of a first thermal interface material positioned between the cover plate and the passive heat-transfer component, a second thermal interface material positioned between the cover plate and the internally cooled cold plate, a third thermal interface material positioned between the passive heat-transfer component and the internally cooled cold plate, a fourth thermal interface material positioned between the passive heat-transfer component and the heat-generating component, and a fifth thermal interface material positioned between the internally cooled cold plate and the processing unit.

16. The cooling system according to claim 14, wherein the processing unit comprises a semiconductor die mounted to a substrate having a plurality of integrated-circuit segments, wherein the internally cooled cold plate is bonded with the semiconductor die and supported by the substrate as a portion of a distinct, packaged processing component, wherein the passive heat-transfer component and the cover plate are configured to be assembled with the packaged processing component and combined into the hybrid cold plate after the packaged processing component, and its internally cooled cold plate, has been installed in an electronic device.

17. The cooling system according to claim 14, wherein the cover plate defines an aperture and the internally cooled cold plate defines a raised portion that extends through the aperture, wherein the raised portion defines a portion of an inlet passage to the internally cooled cold plate, an outlet passage from the internally cooled cold plate, or both.

18. The cooling system according to claim 14, wherein the internally cooled cold plate has another thermal interface region configured to be placed into thermal contact with another passive heat-transfer component, wherein the heat-generating component is a first heat-generating component, the passive heat-transfer component is a first passive heat-transfer component, the hybrid cold plate further comprising a second passive heat-transfer component having a first thermal interface region configured to be placed into thermal contact with the second heat-generating component and a second thermal interface region configured to be placed into thermal contact with the other thermal interface region of the internally cooled cold plate.

19. A method of assembling an electronic device, the method comprising:
coupling a packaged processing unit with an operable substrate, wherein the packaged processing unit comprises an integrated-circuit die and an internally cooled cold plate bonded with a surface of the integrated-circuit die;
placing a passive heat-transfer component into thermal contact with a heat-generating component positioned adjacent the processing unit and into thermal contact with the internally cooled cold plate;
positioning a cover plate overtop the internally cooled cold plate and the passive heat-transfer component; and
urging the cover plate toward the operable substrate, and thereby compressing the internally cooled cold plate and the passive heat-transfer component together.

20. The method according to claim 19, wherein the act of placing the passive heat-transfer component into thermal contact with the heat-generating component positioned adjacent the processing unit and into thermal contact with the internally cooled cold plate comprises positioning a thermal interface material between the passive heat-transfer component and the heat-generating component positioned adjacent the processing unit or the internally cooled cold plate, or both.
